(19) United States
(12) Patent Application Publication
(10) Pub. No.: US 2010/0255722 A1
(43) Pub. Date: Oct. 7, 2010

(54) SEALED PIN HEADER, PIN HEADER CONTACT PIN AND METHOD FOR PROVIDING A SEALED ELECTRICAL CONNECTION BETWEEN ELECTRONIC DEVICES

(76) Inventor: Reinhard Sander, Weibenohe (DE)

Correspondence Address: Harrington & Smith, 4 Research Drive, Suite 202, Shelton, CT, 06484, US

(21) Appl. No.: 12/735,047

(22) PCT Filed: Dec. 19, 2007
(86) PCT No.: PCT/IB2007/055404

§ 371 Date: Jun. 10, 2010

(51) Int. Cl. H01R 13/40; H05K 3/30

(52) U.S. Cl. 439/587; 29/837

(57) ABSTRACT

A sealed pin header including at least one metallic contact pin, a polymeric material substrate with at least one through hole, adapted to receive the at least one metallic contact pin, a portion of the at least one contact pin, which is in contact with inner walls of the through hole of the substrate, is at least partially coated with an elastic material to achieve a sealing between the contact pin and the substrate.

### FIELD OF THE INVENTION

The present invention relates to a sealed pin header and a contact pin for providing an electrical connection between electronic devices. The invention further relates to a method for providing such a sealed electrical connection between a pin header housing and metallic contact pins.

### BACKGROUND OF THE INVENTION

A pin header consists basically of a substrate of a dielectric material, which is commonly provided with a plurality of through holes which are adapted to receive electrically conductive contact pins. The electrically conductive contact pins are provided to connect electronic components. The substrate is e.g. made from polymeric material or epoxy resins, since these materials have advantageous mechanical properties and they provide good chemical and heat resistance. The substrate basically serves to hold and align the contact pins and it provides means for a mechanical coupling with other electric components.

The electric contact pins consist e.g. of a solid wire strand having one end connected e.g. with a circuit board or a counterpart connector and the other end connected to e.g. the wiring of an electronic device. The contact pins are held and aligned by the substrate of the pin header and are often pushed by force into the through holes of the substrate. In this way a reliable mechanical connection of the contact pins with the substrate of the pin header can be established by means of a press-fit. The process of driving the contact pins into the through holes is called stitching.

US 2001/006854 A1 relates to a pin header designed to be mounted on a printed circuit board according to the prior art. The pin header comprises a plurality of pin contacts that are arranged in columns and rows and extend through an insulating substrate, which is provided in the form of a plug connector housing.

EP 1 577 689 A1 describes a pin header for a transceiver. The pin header comprises a rectangular frame which is provided with two rows of five through-holes each. Into these through holes respective metallic contact pins are inserted, which protrude with both ends from opposite surfaces of the frame. The frame is assembled to a printed circuit board (PCB) of a transceiver by soldering the protruding ends of the contact pins of one of the surfaces of the frame with electronic contacts of the PCB. The other ends of the contact pins are free to be connected to another electronic device, like e.g. another PCB or the wiring of an electronic device.

Depending on the application of the pin header, it is sometimes necessary to encapsulate the assembly of pins and substrate in order to achieve e.g. liquid-tight connections. This is in particular the case in automotive applications, where pin headers are often used in the engine compartment to connect the different electronic devices in a vehicle. In the art, this was commonly achieved by a process known as potting. Potting means a process of filling an assembled pin header, i.e. after the contact pins are fitted into their respective through-holes in the substrate of the header, with a liquid sealing compound. The liquid sealing compound flows into any gaps or apertures between the contact pins and the substrate and seals of any remaining leaks. After removing the excess compound the same is hardened or cured by e.g. application of heat or radiation. The finished pin header is thus rendered oil- and watertight, i.e. contact pins and substrate are sealed together.

However, the above described prior potting process has several drawbacks. Potting is not only expensive but also time consuming, as the hardening of the resin takes time. Furthermore, it may result in a pin header with an altered outer surface, which sometimes requires manual reworking. The quality of a sealing provided by means of potting is further dependant on the shape of the potted parts and of the materials used, since some potting compounds function better with certain pin header materials than others.

Beyond that, potting makes high requirements with regard to workplace security and it may cause environmental problems. Further, it requires high investments for the equipment necessary for dispensing and handling of adhesive materials.

The requirement of a sealed pin header, i.e. a pin header which is sealed against e.g. water, oil, moisture, dust, and similar impurities, is very important in many industrial sectors and particular in the automobile sector.

Therefore, it is an object of the present invention to provide a sealed, inexpensive and mechanically stable pin header, which eliminates or reduces the problems and disadvantages experienced in the prior art.

It is a further object of the invention to provide a pin header, which may be used with polymeric or thermoplastic materials, and which may in particular be fastened in holes provided in thermoplastic substrates without widening or destroying the related hole and/or which may compensate for production tolerances or deformations commonly occurring in the thermoplastic substrate due to mechanical or thermal stress. It is still further an object to provide a pin header, which may be fastened in thermoplastic material without getting loose, when the thermoplastic material is subjected to flow (changes its form) over time due to e.g. age or the influence of temperature as it is common for such thermoplastic materials.

### SUMMARY OF THE INVENTION

The above mentioned objects are solved by a pin header according to claim 1, a contact pin for a pin header according to claim 6 and a method according to claim 13. Advantageous embodiments are defined in the dependent claims.

The pin header according to the invention comprises at least one metallic contact pin and a plastic substrate with a plurality of through holes, which are adapted to receive metallic contact pins. A portion of the contact pin which is in contact with inner walls of a through hole of the substrate is at least partially coated to achieve a sealing between the contact pin and the substrate. The sealing is in particular effective against leakage of water, oil, moisture and dust.

The surprising effect of the invention is that due to a relatively simple coating of ordinary contact pins for a pin header a sealed, preferably water tight pin header assembly can be achieved without the need for separate sealing elements, the necessity of tight tolerances or the application of potentially harmful liquid sealing compounds. The manufacturing process of the pin header can remain substantially unchanged. The same machines for the handling of the contact pins and the stitching of the same into the substrate can be used as such with ordinary contact pins according to the prior art. Since any modifications of the complex mass production machinery would be very costly, a sealed, preferably water tight and mechanically stable pin header can be obtained in a cost-efficient way. The pin header may be used with thermoplastic materials and may be fastened in holes provided in thermoplastic substrates without widening or destroying the related hole. Even production tolerances or deformations commonly occurring in the thermoplastic substrate due to mechanical or thermal stress may be compensated thanks to the coating of the pins. The pin header may be fastened in thermoplastic material without getting loose, in case the thermoplastic material is subjected to flow (changes its form) over time due to e.g. age or the influence of temperature as it is common for such thermoplastic materials.

The pin header comprises a substrate of e.g. a thermoplastic material, which is provided with a number of electrically conducting contact pins to connect electrical or electronic components. The substrate is provided with at least one but usually a plurality of through holes which are adapted to receive the contact pins. By the term “plurality” herein at least two through holes, but preferably more, are understood. A through hole is a passage through the substrate, which enables an electrical connection from one side of the substrate to the other, by means of e.g. a contact pin arranged therein.

The electric contact pins are inserted by force (stitched) into the through holes of the substrate to provide a means for an electric connection. For creating a reliable mechanical connection between pins and substrate the contact pins are preferably mounted by means of a press-fit into the through holes. The contact pin(s) is (are) held in the through hole by friction and preferably without the need for screws, glue, solder material or similar. The contact pins may have any suitable shape as common in the art, as e.g. straight, even, tapered, bent, round etc.

The term “partially coated” implies that the coating has to be sufficient to provide a satisfactory sealing. On the other hand the coating should not affect the function of the contact pin(s) to provide an electrical connection between two devices. Obviously, at least one section of the contact pin should remain uncoated to provide an electrical contact surface, in case that an insulating coating is applied.

In a preferred embodiment a good sealing between the contact pin(s) and the substrate is achieved by coating with an elastic material. The elastic material may be a thermoplastic, varnish, rubber, an elastomer, or e.g. thermoplastic elastomer (TPE) or a nitrile rubber as e.g. acrylonitrile butadiene rubber (NBR), or something similar. The material used as coating may be either an insulating or a conductive material. The material used as coating is supposed to be adapted to bear the press-fit within the through hole without a displacement or other degradation of the coating. The coating of the contact pin may be provided as an elastic film which is evenly distributed on the outer surface of the contact pin. Alternatively the coating may be provided in the form of a stopper, i.e. a suitably shaped plug element which surrounds the contact pin and is fitting at least partially in the through hole by an adapted shape (form fit). One advantage of the elastic coating lies in the additionally provided protection in relation to vibration and shock. In other words: due to the elastic coating of the pins the fastening of the same with the substrate is further improved and the risk of detachment of the pins due to e.g. vibrations or aging of the substrate is significantly reduced. Preferably, the coating of the surface of the contact pin is adapted to improve the adhesion to the substrate.

The thickness of the coating is preferably in the range of some tenths of a millimetre, most preferably from 0.01 to 0.5 mm; even more preferred 0.05 to 0.3 mm.

The above mentioned problem is also solved by a contact pin for providing an electrical connection between electronic devices, which contact pin comprises a mechanical fastening portion, and is adapted to be press fitted into a through hole of a pin header substrate. A portion of the contact pin, which is in contact with inner walls of the through hole of the substrate, is at least partially coated to achieve a sealing between the contact pin and the substrate in assembled condition. The term sealing implies a sealing which is in particular effective against leakage of water, oil, moisture and/or dust.

Additionally, the above mentioned problem is solved by a method for providing a sealed electrical connection between electronic devices, comprising the steps of: providing a pin header with a plastic substrate with at least one through hole, providing at least one coated pin header contact pin as described above, stitching of the pin header contact pin into the through hole of the substrate by force, so that a sealing between the contact pin and the substrate is established. Again, the term sealing implies an effective sealing against in particular leakage of water, oil, moisture and/or dust.

### SHORT DESCRIPTION OF THE DRAWINGS

In the following, preferred embodiments are exemplarily described with reference to the enclosed figures, wherein

FIG. 1 is a schematic side view of a coated contact pin with a fastening portion being inserted into a substrate of a pin header;

FIG. 2 is a schematic front view of the contact pin of FIG. 1;

FIG. 3 is a schematic side view of a contact pin with a particular fastening portion and a stopper inserted into a substrate;

FIG. 4 is a schematic front view of the contact pin of FIG. 3;

FIG. 5 is a perspective illustration of a contact pin with the stopper removed and

FIG. 6 is a schematic, partially cut view of an exemplary pin header.

### DESCRIPTION OF ADVANTAGEOUS EMBODIMENTS

In the following, with reference to the drawings, advantageous embodiments of the present invention are described.

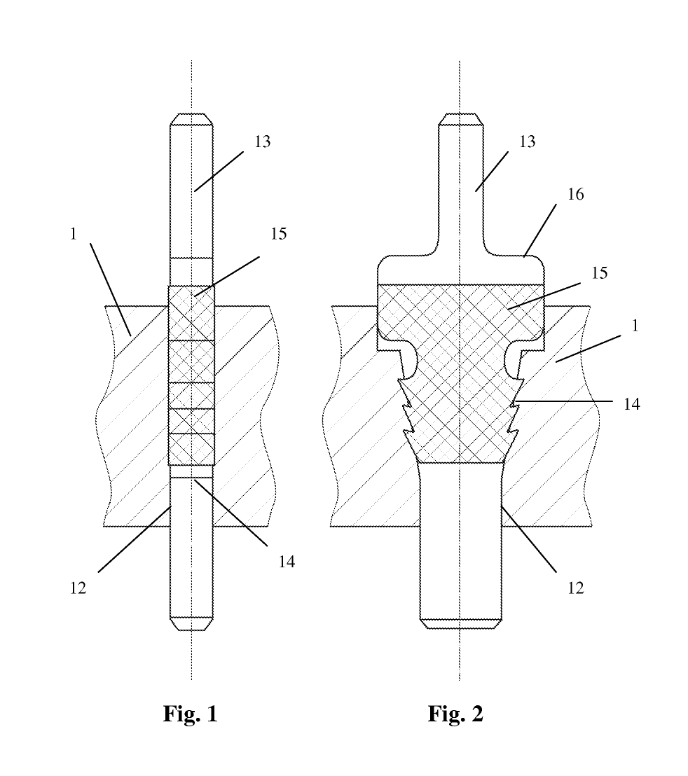

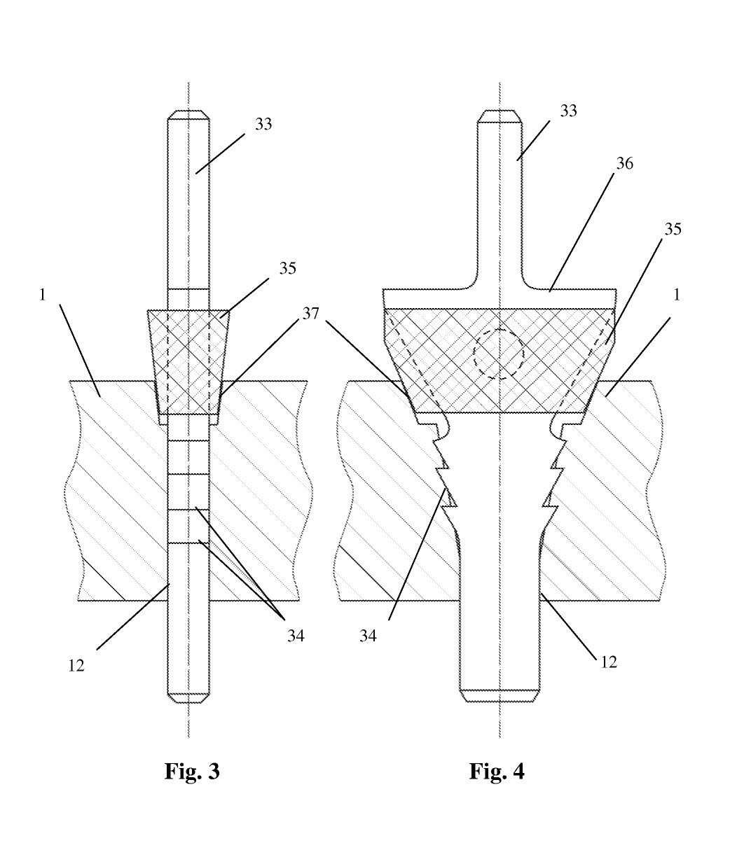

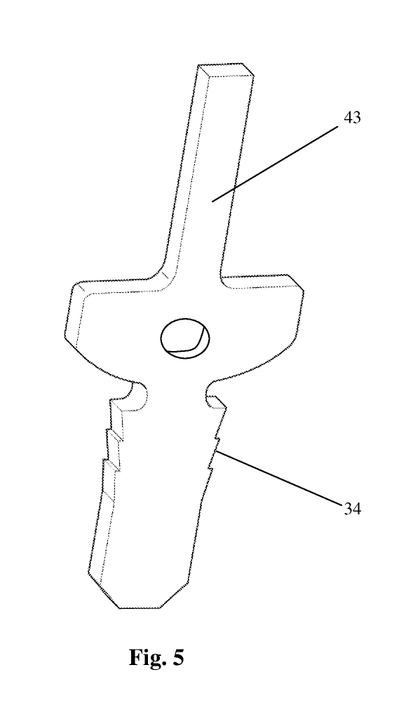

FIGS. 1 and 2 show the same pin from different perspectives; FIG. 1 shows a side view of the pin and FIG. 2 a front view. The same is respectively true for the illustrations shown in FIGS. 3 and 4. It should be noted that the embodiments shown in the Figures are only preferred exemplary embodiments and that also pins with different shapes or cross-sections are feasible, like e.g. pins having a round cross-section.

FIG. 1 shows a section of a substrate 1 of a pin header with a through hole 12 and a contact pin 13 inserted therein. The substrate 1 is for example made from a suitable epoxy resin and the through hole(s) 12 might be machined into the substrate or formed in the same during e.g. the production of the substrate. The contact pin is arranged inside of the through hole 12 by means of a press-fit such that both ends of the pin 13 protrude from opposing surfaces of the substrate 1. In this way it is possible to establish an electrical contact via the two protruding ends of the pin, by e.g. plugging the ends in corresponding sleeves of a mating socket connector. However, it should be noted that the ends of the pins do not necessarily have to protrude from the surface but could also be located inside of the channel defined by the through-hole. In this case e.g. a corresponding contact pin of a mating connector could be inserted into the though-holes to establish contact with the pin located therein. In FIG. 1 a portion of the contact pin 13, which is in contact with the inner walls of the through hole 12 of the substrate 1, is partially coated with an elastic coating 15, shown hatched in the figure. The coating 15 is sufficient for providing a satisfactory sealing between pin 13 and substrate 1 such that no moisture can leak from one surface of the substrate 1 to the other. As one can further see from FIG. 1 the coating still leaves sufficient contact surfaces free on the contact pin 13 to allow an electrical connection.

In the embodiment of FIG. 1 (and FIG. 2) the coating 15 is provided in form of an evenly distributed film to achieve a tight sealing between the contact pin and the substrate 1. In the embodiment of FIG. 3 (and FIG. 4) the coating 35 is rather provided in the form of a plug element in the shape of a truncated cone or a wedge, which surrounds the contact pin and acts like a stopper. The upper surface of the substrate 1 is provided with a correspondingly shaped recess 37 to receive a part of the truncated cone shape, respectively wedge-shape, of the coating, i.e. the stopper. In this way, a tight seal is established. The angle value of the wedge, truncated cone and/or coated portion of the pin is selected to ensure a good fixation.

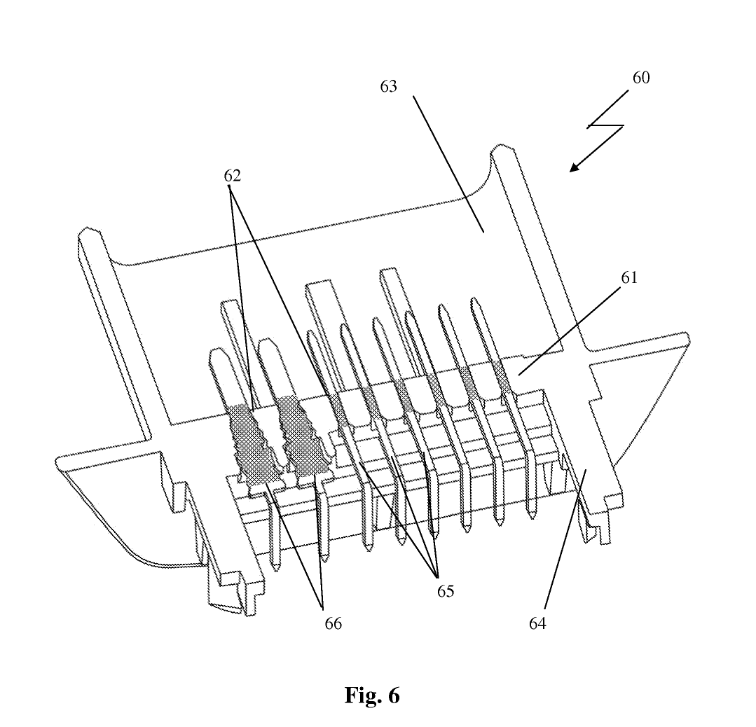

The pins 13 and 33 shown in FIGS. 1 to 4 are stamped out of pieces of sheet metal and have thus rectangular cross-sections. The cross-section and shape of pins 13, 33 may best be seen from the perspective illustration of FIG. 5 where a pin 43 similar to pin 33 is represented (pin 13 would also look in a perspective view similar to pin 33 or 43). In FIG. 5 the contact pin is shown without coating, respectively stopper 35.

Referring again to FIGS. 2 and 4; the pins 13, 33 are provided with enlarged portions 16, 36 which act as stop elements to prevent the pins from being inserted too deep into their respective through holes. Further pins 13, 33 are provided with special mechanical fastening portions 14, 34 having a harpoon-like shape to improve the mechanical connection between the contact pins and the substrate 1. Both coatings 15, 35 on the enlarged portions 16, 36 achieve a reliable sealing between the (in the figures) upper and lower side of the substrate. At the same time the coating additionally improves the fastening of the pins in the through holes.

The contact pins 13 and 33 shown in FIGS. 1 and 3 are mounted by means of a press-fit, i.e. the contact pins are held in the through holes essentially by friction. Due to the preferably elastic coating of the contact pin 13 the fastening and the adhesion of the same with the substrate 1 is further improved and the risk of detachment of the contact pin 13 due to e.g. vibrations or aging of the substrate 1 is significantly reduced. Due to the applied coating, the fastening of the contact pins in holes provided in the substrates can be improved without the necessity for high insertion forces, which are usually necessary to achieve a tight and reliable press-fit and which often lead to widening or destroying of the related holes. Further, the coatings being elastic may compensate for production tolerances or deformations commonly occurring in the thermoplastic substrate due to mechanical or thermal stress. At the same time, the coatings achieve the above described liquid-tightness of the pin header.

Alternatively, the coated contact pins described herein could be overmolded by the material of a pin header during fabrication of the header. In this case naturally no stitching of the pins into holes provided in the header would be necessary.

FIG. 6 is a schematic, partially cut view of an exemplary pin header 60. The pin header is provided with a base portion 61 provided with a number of though-holes 62 extending from one side of the base portion to the other. Further, on both sides of the base portion 61 shoulders 63, 64 extend essentially perpendicular to the plane of the base portion. The shoulders 63, 64 serve for the mechanical coupling of the pin header 60 with corresponding counter-connectors provided e.g. on a printed circuit board (not shown). Inside of the through-holes different kinds of contact pins 65, 66 are arranged. Contact pins 66 are similar to the pins described above under reference to FIGS. 1 to 5 and are provided with harpoon-like fastening portions 67. Contact pins 65 are ordinary contact pins with two straight portions. Both kinds of pins are provided with an elastic coating (indicated by cross-hatching) which establishes an effective sealing between both sides of the base portion 61 of pin header 60. In other words: the apertures formed by the through-holes 62 are effectively sealed against leakage of different kinds by means of the coated contact pins 65, 66 arranged therein.

1. A sealed pin header comprising:
at least one metallic contact pin,
a polymeric material substrate with at least one through hole,
adapted to receive the at least one metallic contact pin,
characterized in that
a portion of the at least one contact pin, which is in contact with inner walls of the through hole of the substrate, is at least partially coated (15; 35) with an elastic material to achieve a sealing between the contact pin and the substrate.

2. The sealed pin header according to claim 1, wherein the coating of the contact pin, which is in contact with the inner walls of the through holes of the substrate, is provided as an elastic film or an elastic stopper with an adapted shape.

3. A contact pin for a pin header for providing an electrical connection between electronic devices,
which contact pin is adapted to be press fitted into a through hole of a pin header substrate,
characterized in that
a portion of the contact pin, which is designed for being in contact with inner walls of the through hole of the substrate, is at least partially coated with an elastic material to achieve a sealing between the contact pin and the substrate in assembled condition.

4. The contact pin according to claim 3, wherein the mechanical fastening portion has a harpoon-like shape.

5. The contact pin according to claim 3, wherein the coating of the contact pin, which is in contact with the inner walls of the through holes of the substrate, is provided as an elastic film or an elastic stopper.

6. A method for providing a sealed electrical connection between electronic devices, comprising the steps of:
providing a pin header with a polymeric material substrate with at least one through hole,
providing at least one pin header contact pin, and
stitching of the pin header contact pins into the through hole of the substrate,
characterized in that
a portion of the contact pin, which is in contact with inner walls of the through hole of the substrate, is at least partially coated with an elastic material to achieve a sealing between the contact pin and the substrate in assembled connection.

7. The method for providing a sealed electrical connection according to claim 6, wherein the coating of the contact pin, which is in contact with the inner walls of the through holes of the substrate, is provided as an elastic film or an elastic stopper.
